(19) United States
(12) Patent Application Publication
(10) Pub. No.: US 2021/0351506 A1
(43) Pub. Date: Nov. 11, 2021

(54) ULTRA-SMALL MILLIMETER WAVE 5G BEAM FORMER ARCHITECTURE

(71) Applicant: Mobix Labs, Inc., Irvine, CA (US)

(72) Inventor: Oleksandr Gorbachov, Irvine, CA (US)

(21) Appl. No.: 17/229,359

(22) Filed: Apr. 13, 2021

Related U.S. Application Data
(60) Provisional application No. 63/020,707, filed on May 6, 2020.

(51) Int. Cl. H01Q 3/36; H01P 5/12; H03F 3/24; H03G 3/30

(52) U.S. Cl. CPC H01Q 3/36; H01P 5/12; H03F 3/245; H03F 2200/451; H03G 2201/103; H03G 2201/307; H03G 3/3042

(57) ABSTRACT

A radio frequency integrated circuit connectible to an array of antenna elements has an RF input/output port and antenna ports that are each connected to respective antenna elements of the array. A transmit-receive amplifier circuit with an amplifier input and an amplifier output is activated during both a transmit mode and a receive mode. An RF switch selectively connects the amplifier input to the RF input/output port and the amplifier output to one of the antenna ports in a transmit mode, and the amplifier input to the one of the antenna ports and the amplifier output to the RF input/output port in a receive mode.

### CROSS-REFERENCE TO RELATED APPLICATIONS

This application relates to and claims the benefit of U.S. Provisional Application No. 63/020,707 filed May 6, 2020 and entitled “ULTRA-SMALL MILLIMETER WAVE 5G BEAM FORMER ARCHITECTURE” the disclosure of which is wholly incorporated by reference in its entirety herein.

### STATEMENT RE: FEDERALLY SPONSORED RESEARCH/DEVELOPMENT

Not Applicable

### BACKGROUND

### 1. Technical Field

The present disclosure relates generally to radio frequency (RF) communications devices, and more particularly, to ultra small-size 5G millimeter wave beamformer architectures.

### 2. Related Art

Wireless communications systems find applications in numerous contexts involving information transfer over long and short distances alike, and a wide range of modalities tailored for each need have been developed. Chief among these systems with respect to popularity and deployment is the mobile or cellular phone. Generally, wireless communications utilize a radio frequency carrier signal that is modulated to represent data, and the modulation, transmission, receipt, and demodulation of the signal conform to a set of standards for coordination of the same. Many different mobile communication technologies or air interfaces exist, including GSM (Global System for Mobile Communications), EDGE (Enhanced Data rates for GSM Evolution), and UMTS (Universal Mobile Telecommunications System).

Various generations of these technologies exist and are deployed in phases, the latest being the 5G broadband cellular network system. 5G is characterized by significant improvements in data transfer speeds resulting from greater bandwidth that is possible because of higher operating frequencies compared to 4G and earlier standards. The air interfaces for 5G networks are comprised of two frequency bands, frequency range 1 (FR1), the operating frequency of which being below 6 GHz with a maximum channel bandwidth of 100 MHz, and frequency range 2 (FR2), the operating frequency of which being above 24 GHz with a channel bandwidth between 50 MHz and 400 MHz. The latter is commonly referred to as millimeter wave (mmWave) frequency range. Although the higher operating frequency bands, and mmWave/FR2 in particular, offer the highest data transfer speeds, the transmission distance of such signals may be limited. Furthermore, signals at this frequency range may be unable to penetrate solid obstacles. To overcome these limitations while accommodating more connected devices, various improvements in cell site and mobile device architectures have been developed.

One such improvement is the use of multiple antennas at both the transmission and reception ends, also referred to as MIMO (multiple input, multiple output), which is understood to increase capacity density and throughput. A series of antennas may be arranged in a single or multi-dimensional array, and further, may be employed for beamforming where radio frequency signals are shaped to point in a specified direction of the receiving device. A transmitter circuit feeds the signal to each of the antennas with the phase of the signal as radiated from each of the antennas being varied over the span of the array. The collective signal to the individual antennas may have a narrower beam width, and the direction of the transmitted beam may be adjusted based upon the constructive and destructive interferences from each antenna resulting from the phase shifts. Beamforming may be used in both transmission and reception, and the spatial reception sensitivity may likewise be adjusted.

In further detail, a typical 5G mm-wave beamformer architecture includes a single RF signal input port and multiple antennas. The transmit signal at the defined carrier frequency is applied to the RF signal input port. The input signal is split into multiple chains using a splitter circuit, which may be a Wilkinson-type splitter. The split portions of the RF input signal are passed to individual transmit chains that may each comprise a phase shifter, a variable gain amplifier (VGA), and a power amplifier (PA), the output of which is connected to a single antenna element.

This interface circuit between the single RF signal input port and the antenna array is configured for receive operations as well, and includes individual receive chains that may each include a low noise amplifier (LNA), a variable gain amplifier, and a phase shifter separate from the one for the transmit chain, with the input to the low noise amplifier being connected to the antenna. There is an intermediate RF switch, typically of the single pole, double throw type in which the pole terminal is connected to the antenna, the first throw terminal is connected to the transmit chain (e.g., the output of the power amplifier), and the second throw terminal is connected to the receive chain (e.g., the input of the low noise amplifier). The output of the receive chain phase shifter is connected to a second RF switch, which is similarly of a single pole, double throw type in which the pole terminal is connected to the inputs of the combiner, the first throw terminal is connected to the transmit chain (e.g., the input of the transmit chain phase shifter), and the second throw terminal is connected to the receive chain (e.g., the output of the receive chain phase shifter). Conventionally, the combiner circuit is also a Wilkinson-type. The splitter and the combiner may be implemented as a single modular component referred to as a splitter-combiner.

The transmit chain and the receive chain may be comprised of separate and independent components aside from the shared intermediate RF switches and the splitter-combiner. However, in some cases, it is also possible for the transmit and receive chains to share certain components, for example, the phase shifter. In such implementations, one port of the phase shifter is connected to the splitter-combiner, and the other port is connected to the pole terminal of the second RF switch.

Current 5G mmWave phased array antenna solutions may utilize up to several hundred individual transmit and receive chains, as the total corresponds to the number of antenna elements in the array, which can be in the hundreds. Each transmit chain and receive chain results in a corresponding increase in the semiconductor die area of the beamformer integrated circuit. Furthermore, each chain contributes to an undesirable increase in DC current drain from the bias supply, increase in switching speed between the transmit and receive chains, and increase in the number of control lines and associated serial peripheral interface (SPI) registers to control each of the circuits.

Accordingly, there is a need in the art for an improved phased array antenna beamformer architecture for multi-channel 5G mmWave applications. There is a need for the RF integrated circuits to have fewer overall circuit components, particularly in the transmit and receive chains thereof. A reduction in the overall die area dedicated to the beamformer circuitry in a single-die RF integrated circuit would also be desirable.

### BRIEF SUMMARY

The present disclosure contemplates improvements in phased array antenna beamformer radio frequency (RF) integrated circuits in which the total number of circuit components are significantly reduced. The embodiments of the integrated circuits may be utilized in 5G mmWave systems, though the present disclosure may find application in any other suitable applications of array antenna RFICs. In one embodiment, the die area in the RFIC dedicated to the transmit chain and receive chain circuit components can be significantly reduced, and preferably almost halved.

According to one embodiment of the present disclosure, a phased array beamformer circuit may be connectible to an array of antenna elements. The circuit may include an RF input-output port, along with one or more antenna ports that may each be connectible to a respective one of the antenna elements. There may also be a splitter-combiner including a combined port that is connected to the RF input-output port, as well as one or more split ports. The circuit may include one or more variable gain amplifier circuits that each have an input and an output, and one or more power amplifier circuits each of which may likewise have an input and an output. The circuit may include one or more RF switches. Each of the RF switches may have a first pole terminal that is connected to a split-side junction in electrical communication with a corresponding one of the split-ports of the splitter-combiner. The RF switches may also have a second pole terminal that is connected to an antenna-side junction in electrical communication with a corresponding one of the antenna ports. Furthermore, the RF switch may include a first set of throw terminals and a second set of throw terminals that may each alternatingly connect the first pole terminal to the input of a given one of the variable gain amplifier circuits and the output of a corresponding one of the power amplifier circuits connected thereto, the second pole terminal to the output of the given one of the power amplifier circuits and the input of a corresponding one of the variable gain amplifier circuits connected thereto.

Another embodiment of the present disclosure may be a phased array beamformer circuit that is connectible to an array of antenna elements. The circuit may include an RF input-output port, as well as one or more antenna ports that may each be connectible to a respective one of the antenna elements. The circuit may also include a splitter-combiner that has a combined port connected to the RF input-output port and one or more split ports. Additionally, the circuit may include one or more first amplifier circuits that may each have an input and an output. The circuit may include one or more first RF switches that each have a first pole terminal that is in electrical communication with a corresponding one of the split ports of the splitter-combiner, a second pole terminal, and a first set of throw terminals and a second set of throw terminals each alternatingly connecting the input and the output of a given one of the first amplifier circuits to the first pole terminal and the second pole terminal. The circuit may further include one or more second amplifier circuits that each have an input and an output. The circuit may also include one or more second RF switches, each of which may have a first pole terminal that is connected to the second pole terminal of a corresponding one of the first RF switches, a second pole terminal that is in electrical communication with a corresponding one of the antenna ports, and a first set of throw terminals and a second set of throw terminals each alternatingly connecting the input and the output of the second amplifier of a given one of the second amplifier circuits to the first pole terminal and the second pole terminal.

In yet another embodiment of the present disclosure, there may be a radio frequency integrated circuit that is connectible to an array of antenna elements. The integrated circuit may include an RF input/output port and antenna ports that may each be connected to respective antenna elements of the array. The integrated circuit may also include a transmit-receive amplifier circuit with an amplifier input and an amplifier output. The transmit-receive amplifier circuit may be activated during both a transmit mode and a receive mode. There may be an RF switch that selectively connects the amplifier input to the RF input/output port and the amplifier output to one of the antenna ports in a transmit mode, and the amplifier input to the one of the antenna ports and the amplifier output to the RF input/output port in a receive mode.

The present disclosure will be best understood accompanying by reference to the following detailed description when read in conjunction with the drawings.

### BRIEF DESCRIPTION OF THE DRAWINGS

These and other features and advantages of the various embodiments disclosed herein will be better understood with respect to the following description and drawings, in which like numbers refer to like parts throughout, and in which:

FIG. 1A is a schematic diagram of a first embodiment of a phased array beamformer circuit with a dual pole, dual throw switch interconnecting a power amplifier and a variable gain amplifier for both transmit and receive mode operation;

FIG. 1B is a schematic diagram of the first embodiment of the phased array beamformer circuit shown with active switch connections in a transmit mode;

FIG. 1C is a schematic diagram of the first embodiment of the phased array beamformer circuit shown with the active switch connections in a receive mode;

FIG. 2 is a schematic diagram of a second embodiment of the phased array beamformer circuit with a phase shifter being isolated from certain switch terminals;

FIG. 3 is a schematic diagram of a third embodiment of the phased array beamformer circuit with the phase shifter being connected between the variable gain amplifier and the power amplifier;

FIG. 4 is a schematic diagram of a fourth embodiment of the phased array beamformer circuit with a configuration to accommodate gain requirements while maintaining proper isolation between the pole and throw terminals of the switch;

FIG. 5A is a schematic diagram of a fifth embodiment of the phased array beamformer circuit including an additional RF switch to reduce insertion loss in a transmit mode operation;

FIG. 5B is a schematic diagram of the fifth embodiment of the phased array beamformer circuit with active switching connections thereof in the transmit mode;

FIG. 5C is a schematic diagram of the fifth embodiment of the phased array beamformer circuit with active switching connections thereof in the receive mode;

FIG. 6A is a schematic diagram of a sixth embodiment of the phased array beamformer circuit including a power amplifier-low noise amplifier block without a phase shifter stage;

FIG. 6B is a schematic diagram of the sixth embodiment of the phased array beamformer circuit with active switching connections thereof in the transmit mode;

FIG. 6C is a schematic diagram of the sixth embodiment of the phased array beamformer circuit with active switching connections thereof in a high sensitivity receive mode; and

FIG. 6D is a schematic diagram of the sixth embodiment of the phased array beamformer circuit with active switching connections thereof in a low current receive mode.

### DETAILED DESCRIPTION

The present disclosure encompasses various embodiments of a radio frequency (RF) integrated circuit for ultra small size 5G millimeter wave phased antenna array beamformer architectures. The number of circuit components, including amplifiers, control lines, and bias supplies for implementing the transmit and receive chains may be reduced in accordance with these embodiments, with concomitant reductions in die real estate. The switching times between transmit mode operation and receive mode operation may also be reduced, leading reduced latency between communicating nodes utilizing such RF integrated circuits.

The detailed description set forth below in connection with the appended drawings is intended as a description of the several presently contemplated embodiments of the RF integrated circuit and is not intended to represent the only form in which the disclosed invention may be developed or utilized. The description sets forth the functions and features in connection with the illustrated embodiments. It is to be understood, however, that the same or equivalent functions may be accomplished by different embodiments that are also intended to be encompassed within the scope of the present disclosure. It is further understood that the use of relational terms such as first and second and the like are used solely to distinguish one from another entity without necessarily requiring or implying any actual such relationship or order between such entities.

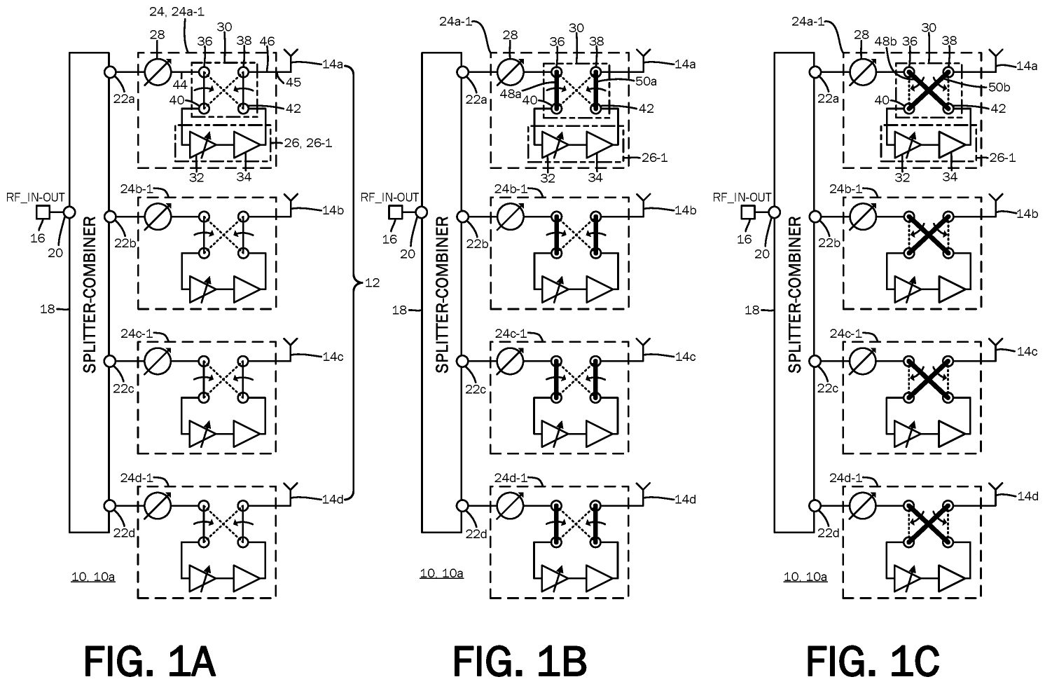

The schematic diagram of FIG. 1 illustrates a first embodiment of an RF integrated circuit 10a, and specifically an aspect thereof that is a phased array antenna beamformer. Although the present disclosure may interchangeably reference the beamformer and the RF integrated circuit 10, the beamformer may be a part of a broader RF circuit that includes transmitters, receivers, baseband modules, and so forth. Such components have been omitted from the schematic diagrams of the present disclosure but may be part of a single integrated circuit package, or even a single semiconductor die. However, there may also be some embodiments in which the beamformer is implemented in a discrete die and independently packaged without additional components. It is deemed to be within the purview of the those having ordinary skill in the art to implement the RF integrated circuit 10 in any matter suitable for a given application.

The illustrated RF integrated circuit 10 may be utilized as part of a 5G mnWave phased array antenna architecture. As understood, the 5G mobile network standard is comprised of FR1 and FR2 frequency ranges, with FR2 being commonly referred to as millimeter wave or mmWave because the operating frequency is above 24 GHz to 50 GHz. There are discrete frequency bands with defined bandwidths and may be referred to as low band or high band, e.g., 24-30 GHz as low-band and 37-44 GHz as high-band.

For purposes of simplification, the embodiments of the present disclosure are described in reference to a phased antenna array 12 with four antenna elements 14, including a first antenna element 14a, a second antenna element 14b, a third antenna element 14c, and a fourth antenna element 14d. It will be appreciated that a typical 5G mmWave architecture operates with significantly larger antenna arrays with additional antenna elements.

In a phased array antenna architecture, a separate transmit signal is fed to each of the antenna elements 14 in the array 12, with some signals being phase shifted relative to another that causes constructive and destructive interference that makes beam over the air directionality possible. In this regard, a single RF transmit signal is split for the separate antenna elements 14. Likewise, the received RF signal are transduced by each of the individual antenna elements 14 and yield multiple RF receive signals, some of which may be phase shifted relative to the others. The phase shifts are then reversed and combined into a single RF output signal.

The RF integrated circuit 10 includes an RF input-output port 16 to which a combined RF signal from a transmitter is applied, and from which a combined RF signal to a receiver is output. In accordance with phased antenna architectures, a splitter-combiner 18 splits the combined RF signal on the RF input-output port 16 into multiple RF signals destined for each of the antenna elements 14 and combines the separate RF signals received from each of the antenna elements 14. The splitter-combiner 18 has a single combined port 20, and one or more split ports 22. In the illustrated example, the splitter-combiner 18 has four split ports 22: a first split port 22a, a second split port 22b, a third split port 22c, and a fourth split port 22d corresponding to the antenna elements 14a, 14b, 14c, and 14d, respectively. The splitter-combiner 18 is understood to be a Wilkinson-type splitter and combiner circuit, though any other suitable splitter/combiner circuit known in the art or subsequently developed may be utilized without departing from the scope of the present disclosure.

The embodiments of the present disclosure contemplate one or more transmit-receive circuits 24 that interface with the antenna elements 14. Like the splitter-combiner 18 with split ports 22a-22d corresponding to each of the antenna elements 14a-14d, there are corresponding transmit-receive circuits 24 therefor. In this first embodiment of the RF integrated circuit 10a, a first variation 24-1 of the transmit-receive circuit is contemplated. Specifically, there is a first transmit-receive circuit 24a-1 that is connected to the first split port 22a and to the first antenna element 14a, a second transmit-receive circuit 24b-1 that is connected to the second split port 22b and to the second antenna element 14b, a third transmit-receive circuit 24c-1 that is connected to the third split port 22c and to the third antenna element 14c, and a fourth transmit-receive circuit 24d-1 that is connected to the fourth split port 22d and to the fourth antenna element 14d.

In further detail, the first embodiment of the transmit-receive circuit 24-1 includes a phase shifter 28, an RF switch 30, a variable gain amplifier 32, and a power amplifier 34. The phase shifter 28, which is understood to be bi-directional, has a first port that is connected to the split port 22 of the splitter-combiner 18, as well as a second port that is connected to the RF switch 30.

According to the illustrated embodiment, the RF switch 30 is a double pole, double throw (DPDT) switch a first pole terminal 36, a second pole terminal 38, a first set of throw terminals 40, and a second set of throw terminals 42. It is understood that a DPDT switch is typically implemented with two poles and four throw terminals, but for purposes of the schematic diagrams of the present disclosure, each pair of throw terminals is depicted as one terminal or port as is convention. A DPDT may be configured with two single pole, double throw (SPDT) switches, with the pole of the first SPDT switch corresponding to the first pole terminal 36 and the pole of the second SPDT switch corresponding to the second pole terminal 38. The connection between the pole of the first SPDT switch are toggled between the two throws thereof, while the connection between the pole of the second SPDT switch are toggled between the two throws thereof. Thus, when referring to the set of throw terminals, it is understood to refer to a throw of the first SPDT switch and a throw of the second SPDT switch. In other words, the first set of throw terminals includes the first throw of the first SPDT switch and the first throw of the second SPDT switch, and the second set of throw terminals includes the second throw of the first SPDT switch and the second throw of the second SPDT switch. Suitable jumper connections interconnecting the throw terminals can be implemented. The foregoing description of the DPDT switch/RF switch 30 is exemplary only, and any other suitable configuration may be substituted without departing from the present disclosure. Along these lines, any other reference to the RF switch 30, whether or not shown in the figures as a DPDT switch, is understood to encompass any and all implementations of the same.

The first pole terminal 36 is connected to a split-side junction 44 that is in electrical communication with the split port 22 of the splitter-combiner 18. The split-side junction 44 is connected to the second port of the phase shifter 28, and eventually to the split port 22.

The second pole terminal 38 is connected to an antenna-side junction 46 that is in electrical communication with the antenna element 14. The first embodiment of the transmit-receive circuit 24-1 may include an antenna port 45 to which the antenna element 14 is connected, though it may merely constitute the logical junction separating the antenna element 14 from what is broadly defined as the transmit-receive circuit 24. In this regard, the antenna port 45 may be a contiguous conductive trace with no discernible physical embodiment of a port or other physical interface where one structure is connected to another. Along these lines, to the extent ports and other structural features that may imply a physical interface between one component or another are referenced in the present disclosure, similar logical interfaces between feature blocks and/or components are intended thereby.

As indicated above, the first embodiment of the transmit-receive circuit 24-1 includes the variable gain amplifier 32 and the power amplifier 34. These two amplifier circuits may be collectively referred to as a transmit-receive amplifier circuit 26, with the illustrated first embodiment being identified as the transmit-receive amplifier circuit 26-1. Additional variations will be described below, but the first embodiment of the transmit-receive amplifier circuit 26-1 contemplates the variable gain amplifier 32 being connected in series with the power amplifier 34. That is, the output of the variable gain amplifier 32 is fed into the input of the power amplifier, with the input of the variable gain amplifier 32 corresponding to the input of the transmit-receive amplifier circuit 26-1, while the output of the power amplifier 34 corresponds to the output of the transmit-receive amplifier circuit 26-1. The variable gain amplifier 32 may be comprised of multiple stages, though only a single one is illustrated in the schematic diagram. Furthermore, the variable gain amplifier 32 is understood to be tuned for a low noise figure, while the power amplifier 34 is tuned for high power and linearity.

The isolation between the first pole terminal 36 and the second pole terminal 38 is understood to be a function of the combined gain of the variable gain amplifier 32 and the power amplifier 34. In a preferred embodiment, this isolation may be at least 5 dB, and up to 10 dB higher than the total gain of the transmit-receive amplifier circuit 26.

The first set of throw terminals 40 of the RF switch 30 are connected to the input of the transmit-receive amplifier circuit 26-1, and the second set of throw terminals 42 of the RF switch 30 are connected to the output of the transmit-receive amplifier circuit 26-1. The RF switch 30 is operated to alternatingly connect the first pole terminal 36 to the input of the transmit-receive amplifier circuit 26-1, e.g., the input of the variable gain amplifier 32, and the output of the transmit-receive amplifier circuit 26-1, e.g., the output of the power amplifier 34. The RF switch 30 is also operated to alternatingly connect the second pole terminal 38 to the output of the transmit-receive amplifier circuit 26-1, e.g., the output of the power amplifier 34, and the input of the transmit-receive amplifier circuit 26-1, e.g., the input of the variable gain amplifier 32. The specifics of each of these switch connections will be described in further detail below.

The configuration of the first embodiment of the transmit-receive circuit 24-1 is understood to be replicated for each of the first transmit-receive circuit 24a-1, the second transmit-receive circuit 24b-1, the third transmit-receive circuit 24c-1, and the fourth transmit-receive circuit 24d-1. Accordingly, the details thereof as pertaining to the second, third, and fourth transmit-receive circuit and will not be repeated for the sake of brevity.

FIG. 1B illustrates the connections that are established in the RF switch 30 during transmit mode operations. Specifically, the first pole terminal 36 of the RF switch 30 is connected to the first set of throw terminals 40 over a first pole connection 48a, which is in turn connected to the input of transmit-receive amplifier circuit 26-1 corresponding to the input of the variable gain amplifier 32. The second pole terminal 38 of the RF switch is connected to the second set of throw terminals 42 over a second pole connection 50a, which is in turn connected to the output of the transmit-receive amplifier circuit 26-1 corresponding to the output of the power amplifier 34.

A transmit signal applied to the RF input-output port 16 and split to the split ports 22a-22d. With the signal output from the split port 22a in particular, it is passed to the phase shifter 28 with a corresponding phase shift being applied thereto, then to the first pole terminal 36 of the RF switch 30. The split and phase shifted RF signal is passed from the first pole terminal 36 to the first set of throw terminals 40 over the first pole connection 48, and then amplified by the variable gain amplifier 32. The power amplifier 34 further amplifies this signal, and is passed to the second set of throw terminals 42. Then, the signal is passed to the second pole terminal 38 over the second pole connection 50a, and output to the antenna element 14a.

FIG. 1C illustrates the connections that are established in the RF switch 30 during receive mode operations. The second pole terminal 38 of the RF switch 30 is connected to the first set of throw terminals 40 over a second pole connection 50b. Again, the first set of throw terminals 40 is connected to the input of the transmit-receive amplifier circuit 26-1, which corresponds to the input of the variable gain amplifier. The output of the power amplifier 34, which corresponds to the output of the transmit-receive amplifier circuit 26-1, is still connected to the second set of throw terminals 42. However, over a first pole connection 48b, the second set of throw terminals 42 is now connected to the first pole terminal 36.

An incoming RF signal received on the antenna element 14a is passed to the second pole terminal 38 and to the input of the transmit-receive amplifier circuit 26-1 over the second pole connection 50b and through the first set of throw terminals 40. The received signal is amplified first by the variable gain amplifier 32, followed by another amplification stage by the power amplifier 34. The amplified receive signal is then passed to the second set of throw terminals 42 of the RF switch, and to the first pole terminal 36 over the first pole connection 48b. With the first pole terminal 36 being connected to the phase shifter 28, the amplified receive signal is phase shifted, and passed to the split port 22a of the splitter-combiner 18. Other signals received on the second antenna element 14b, third antenna element 14c, and fourth antenna element 14d are similarly amplified by the respective transmit-receive circuits 24b-1, 24c-1, and 24d-1 connected thereto, then passed to the respective split ports 22b, 22c, and 22d. Each of these signals are combined by the splitter-combiner 18, and output from the combined port 20 as a single RF receive signal through the RF input-output port 16.

As will be understood from the foregoing, the transmit-receive amplifier circuit 26-1 remain turned on during both the transmit mode operation and the receive mode operation. The RF switch 30 toggles the input to the transmit-receive amplifier circuit 26 between the splitter-combiner 18 and the antenna elements 14, and the output from the transmit-receive amplifier circuit 26 likewise between the antenna elements 14 and the splitter-combiner, respectively. In effect, the transmit-receive amplifier circuit 26 is utilized for both transmit and receive operations. The operating characteristics of the transmit-receive amplifier circuit 26 may be adjusted depending on whether it is in the transmit mode or the receive mode. Specifically, the DC biasing current settings for the variable gain amplifier 32 and the power amplifier 34 may be differently set for each mode.

The foregoing configuration of the RF integrated circuit 10 significantly reduces the number of active amplifier stages, biasing blocks, and associated digital control circuits and serial peripheral interface registers. In a preferred embodiment, the number of circuit components may almost be halved. Although conventional phased array antenna RF integrated circuits independently switch the transmit amplifiers and the receive amplifiers on and off to save DC current, this leads to significant time delays between the application of the control signal and setting the required parameters for those circuits. With the transmit-receive amplifier circuits 26 being constantly on in accordance with the embodiments of the present disclosure, this switching is no longer necessary between transmit and receive mode operation. Whereas conventionally the delays can be as long as hundreds of nanoseconds to several microseconds, the present disclosure envisions transmit-receive switching to be no more than a few nanoseconds. This is understood to result in reduced latency in communications between active nodes.

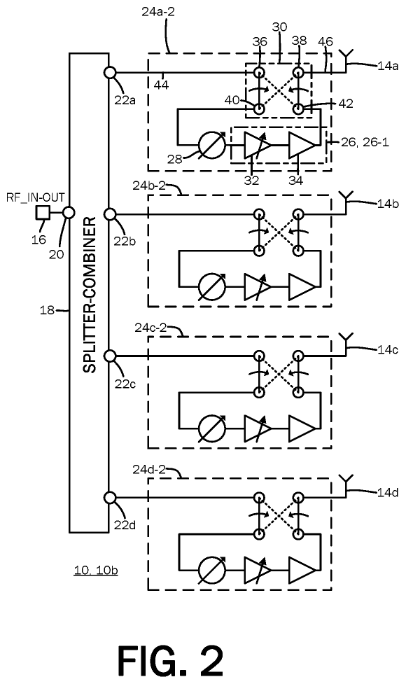

FIG. 2 illustrates a second embodiment of the RF integrated circuit 10b with an alternative, second variation 24-2 of the transmit-receive circuit. As with the first embodiment 10a, the second embodiment of the RF integrated circuit 10b is a beamformer that may be utilized as part of a 5G mnWave phased array antenna architecture. To this end, there is the RF input-output port 16, the splitter-combiner 18 with the single combined port 20 and the one or more split ports 22. A first transmit-receive circuit 24a-2 is connected to the first split port 22a and to the first antenna element 14a, a second transmit-receive circuit 24b-2 is connected to the second split port 22b and the second antenna element 14b, a third transmit-receive circuit 24c-2 is connected to the third split port 22c and the third antenna element 14c, and a fourth transmit-receive circuit 24d-2 is connected to the fourth split port 22d and the fourth antenna element 14d.

The second variation of the transmit-receive circuit 24-2 also incorporates the phase shifter 28, the RF switch 30, and the transmit-receive amplifier circuit 26 with the variable gain amplifier 32 and the power amplifier 34, but is configured to further mitigate RF switch isolation demands. In further detail, the split-side junction 44 is connected directly to the first pole terminal 36 instead of the phase shifter 28 as in the first variation of the transmit-receive circuit 24-1. The first set of throw terminals 40 is connected to one port of the phase shifter 28, with the second port of the same being connected to the input of the transmit-receive amplifier circuit 26. In this embodiment, the phase shifter 28 may be either unidirectional or bidirectional. It is expressly contemplated that the same first embodiment of the transmit-receive amplifier circuit 26-1 is utilized here, with the variable gain amplifier 32 connected in series with the power amplifier 34. The output of the power amplifier 34 corresponds to the output of the transmit-receive amplifier circuit 26, and is connected to the second set of throw terminals 42. The second pole terminal 38 is in turn connected to the antenna-side junction 46, and the antenna element 14. It is understood that conventional phase shifters 28 are lossy, and the configuration of the second embodiment of the transmit-receive circuit 24-2 is envisioned to reduce the isolation requirements between the first pole terminal 36 and the second pole terminal 38. The foregoing configuration is replicated across each of the transmit-receive circuits 24b-3, 24c-3, and 24d-4, and will not be repeated for the sake of brevity.

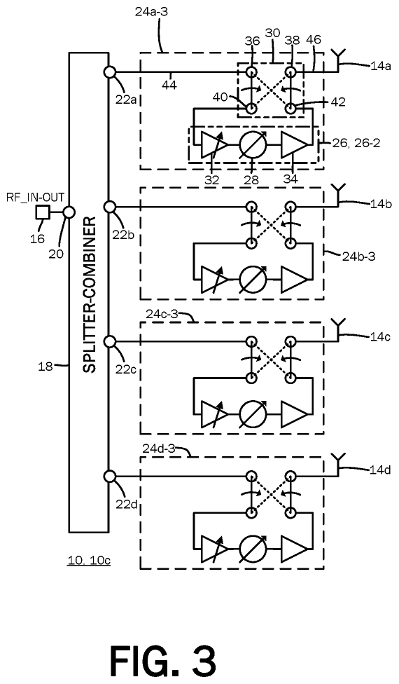

FIG. 3 illustrates a third embodiment of the RF integrated circuit 10c with an alternative, third variation 24-3 of the transmit-receive circuit. As with the first embodiment 10a and the second embodiment 10b, the third embodiment of the RF integrated circuit 10b is a beamformer that may be utilized as part of a 5G mnWave phased array antenna architecture. Likewise, there is the RF input-output port 16, the splitter-combiner 18 with the single combined port 20 and the one or more split ports 22. A first transmit-receive circuit 24a-3 is connected to the first split port 22a and to the first antenna element 14a, a second transmit-receive circuit 24b-3 is connected to the second split port 22b and the second antenna element 14b, a third transmit-receive circuit 24c-3 is connected to the third split port 22c and the third antenna element 14c, and a fourth transmit-receive circuit 24d-3 is connected to the fourth split port 22d and the fourth antenna element 14d.

In general, the third embodiment of the transmit-receive circuit 24-3 utilizes the same foundational components as the other embodiments, including the phase shifter 28, the RF switch 30, the variable gain amplifier 32, and the power amplifier 34, though configured differently. Again, the split-side junction 44 that is connected to the split port 22 of the splitter-combiner 18 is tied to the first pole terminal 36, and the second pole terminal 38 is tied to the antenna-side junction 46 that is connected to the antenna element 14. The transmit-receiver circuit 24-3 utilizes an alternatively configured second embodiment of the transmit-receive amplifier circuit 26-2. The first set of throw terminals 40 is still connected to the input of the transmit-receive amplifier circuit 26, and the second set of throw terminals 42 is connected to the output of the transmit-receive amplifier circuit 26. The input of the variable gain amplifier 32 corresponds to such input of the overall transmit-receive amplifier circuit 26-2, and the output of the power amplifier 34 corresponds to the output of the overall transmit-receive amplifier circuit 26-2. The output of the variable gain amplifier 32 is connected to the first port of the phase shifter 28, and its second port is connected to the input of the power amplifier 34.

Connecting the phase shifter 28 before the input of the transmit-receive amplifier circuit 26-1 as in the second embodiment of the RF integrated circuit 10b may involve utilizing a phase shifter 28 with low loss and low noise figure operating characteristics so that sensitivity in the receive mode operations is not degraded. To mitigate against such loss in sensitivity, the second embodiment the transmit-receive amplifier circuit 26-2 locates the variable gain amplifier 32 before/in front of the phase shifter 28. The variable gain amplifier 32 may be tuned for a low noise figure, which is understood to maximize sensitivity during receive mode operations. Furthermore, this embodiment is contemplated to reduce noise contribution limits for transmitter circuitry providing signals to the RF input-output port 16. The foregoing configuration of the third embodiment of the transmit-receive circuit 24a-3 is understood to be replicated across each of the other transmit-receive circuits 24b-3, 24c-3, and 24d-3, so the details thereof will not be repeated.

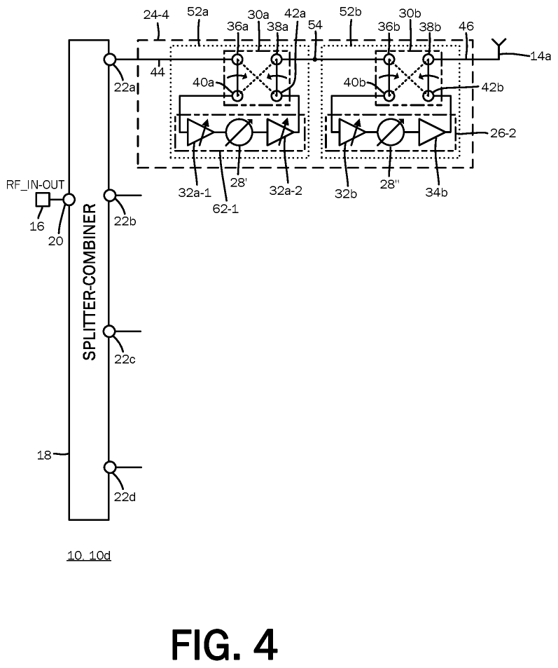

The first, second and third embodiments of the RF integrated circuit 10a-10c may necessitate transmit-receive amplifier circuits with high gain across the entire transmit chain/receive chain. As such, achieving the thresholds for isolation between the pole terminals of the RF switch 30 in order to ensure proper operation may present a further challenge. The schematic diagram of FIG. 4 illustrates a fourth embodiment of the RF integrated circuit 10d with a fourth variation of a transmit-receive circuit 24-4. This embodiment also incorporates the RF input-output port 16 and the splitter-combiner 18 with the combined port 20 and the one or more split ports 22. The transmit-receive circuit 24-4 is connected to the first split port 22a and to the first antenna element 14a. While FIG. 4 does not show the other antenna elements 14 or the transmit-receive circuits 24, they are understood to be incorporated into the full embodiment; the depictions thereof in FIG. 4 have been removed for the sake of simplicity.

The fourth variation of the transmit-receive circuit 24-4 contemplates balancing gain and RF switch isolation parameters by dividing the circuit into multiple stages of common elements. The transmit-receive circuit 24-4 is defined by a first stage 52a and a second stage 52b. In further detail, the first stage 52a includes a first stage RF switch 30a with a first pole terminal 36a and a second pole terminal 38a. Additionally, the first stage RF switch 30a includes a first set of throw terminals 40a and a second set of throw terminals 42a. The first pole terminal 36a is in electrical communication with the split port 22 over the split-side junction 44, while the second pole terminal 38a is connected to an interstage junction 54.

The first stage 52a includes a first variation of a variable gain amplifier circuit 62-1, including a first variable gain amplifier 32a-1, the input thereof corresponding to the overall input of the variable gain amplifier circuit 62-1. The output of the first variable gain amplifier 32a-1 is connected to the first port of the phase shifter 28′, with the second port thereof being connected to the input of a second variable gain amplifier 32a-2. The output of the second variable gain amplifier 32a-2, which generally corresponds to the overall output of the variable gain amplifier circuit 62-1, is connected to the second set of throw terminals 42a of the first stage RF switch 30a.

The second stage 52b includes a second stage RF switch 30b similarly with a first pole terminal 36b and a second pole terminal 38b. The first pole terminal 36b is connected to the interstage junction 54, so the second pole terminal 38a of the first stage RF switch 30a is connected to the first pole terminal 36a of the second stage RF switch 30b. The second pole terminal 38b is connected to the antenna-side junction 46, which in turn is connected to the antenna element 14.

The second stage 52b utilizes the second embodiment of the transmit-receive amplifier circuit 26-2, which includes the variable gain amplifier 32b with an input that generally corresponds to the overall input of the same. The output of the variable gain amplifier 32b is connected to the first port of the phase shifter 28″, which its second port is connected to the input of the power amplifier 34b. The output of the power amplifier 34b, which generally corresponds to the overall output of the transmit-receive amplifier circuit 26-2, is connected to the second set of throw terminals 42b of the second stage RF switch 30b. The isolation between the first pole terminal 36b and the second pole terminal 38b of the second stage RF switch 30b is envisioned to be the same or substantially the same as between the first pole terminal 36a and the second pole terminal 38a of the first stage RF switch 30a, e.g., 5 to 10 dB higher than the gain of the respective amplifier circuit.

The foregoing configuration contemplates distributing the variable gain amplifier 32 and the phase shifter 28 across multiple stages, e.g., the first stage 52a and the second stage 52b. Those having ordinary skill in the art will recognize other possible configurations in which such distribution can be achieved, including configurations with additional RF switches 30.

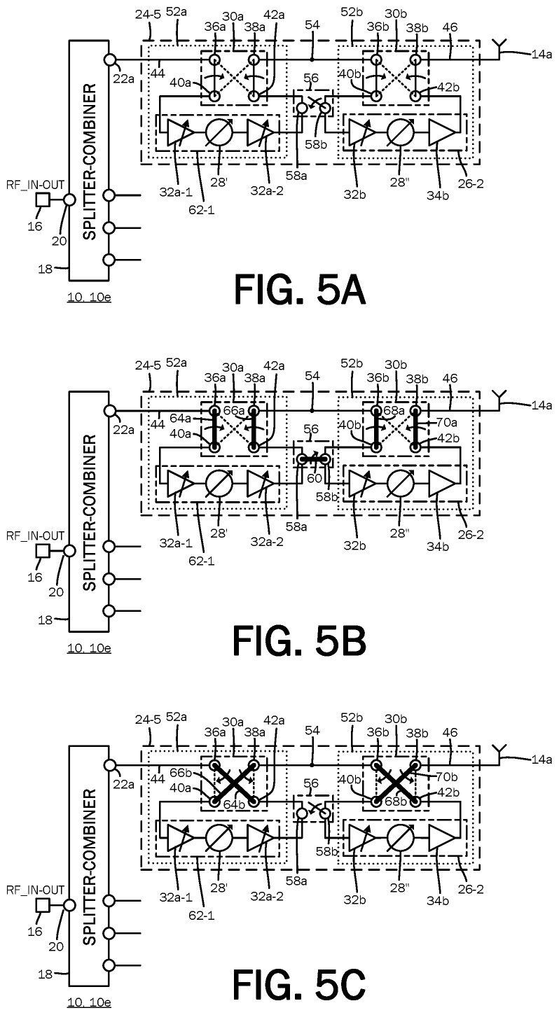

With reference to the schematic diagram of FIGS. 5A-5C, a further variation on RF integrated circuit 10e incorporates a fifth variation of a transmit-receive circuit 24-5. Again, this embodiment has the RF input-output port 16 and the splitter-combiner 18 with the combined port 20 and the one or more split ports 22. The transmit-receive circuit 24-5 is connected to the first split port 22a and to the first antenna element 14a. While FIGS. 5A-5C do not show the other antenna elements 14 or the transmit-receive circuits 24, they are understood to be incorporated into the full embodiment; the depictions thereof in FIGS. 5A-5C have been removed for the sake of simplicity.

Beyond the contemplated advantages of the fourth variation of the transmit-receive circuit 24-4 discussed above, the fifth variation 24-5 contemplates a reduction of insertion loss during transmit mode operations. Accordingly, the gain of the transmit-receive circuit 24 may be increased while reducing DC current consumption. The transmit-receive circuit 24-5 is defined by the first stage 52a and a second stage 52b. The first stage 52a includes a first stage RF switch 30a with the first pole terminal 36a and the second pole terminal 38a. Additionally, the first stage RF switch 30a includes the first set of throw terminals 40a and the second set of throw terminals 42a. The first pole terminal 36a is in electrical communication with the split port 22 over the split-side junction 44, while the second pole terminal 38a is connected to the interstage junction 54.

The first stage 52a includes the first variation of a variable gain amplifier circuit 62-1, the input of which is connected to the first set of throw terminals 40a, and the output of which is connected to the second set of throw terminals 40b. The second stage 52b likewise includes the second stage RF switch 30b with the first pole terminal 36b connected to the interstage junction 54. Additionally, the second pole terminal 38b of the second stage RF switch 30b is connected to the antenna-side junction 46, which in turn is connected to the antenna element 14. The second stage 52b utilizes the second embodiment of the transmit-receive amplifier circuit 26-2, also discussed in detail above.

The fifth variation of the transmit-receive circuit 24-5 further incorporates an interstage switch 56 with one terminal 58a (e.g., the throw terminal) connected to the output of the variable gain amplifier circuit 62-1, and another switch terminal 58b (e.g., the pole terminal) connected to the input of the transmit-receive amplifier circuit 26-2. In one implementation, the interstage switch 56 is a single pole, single throw switch that connects the output of the variable gain amplifier circuit 62-1 and the input of the transmit-receive amplifier circuit 26-2 together during the transmit mode. In the receive mode, the interstage switch 56 is disengaged to separate the respective output and input of the amplifier circuits 62-1 and 26-2.

The schematic diagram of FIG. 5B illustrates the switch connections that are made during transmit mode operation. The transmit signal is applied to the RF input-output port 16 and passed to the combined port 20 of the splitter-combiner 18 to be separated to multiple transmit chains. One of the split signals is output from the first split port 22a, and passed to the first stage RF switch 30a, specifically the first pole terminal 36a thereof. Over a first pole connection 64a, the first pole terminal 36a is connected to the first set of throw terminals 40a, and so the transmit signal is passed to the input of the variable gain amplifier circuit 62-1. After being amplified in a first step by the variable gain amplifier 32a-1, passed through the phase shifter 28′, and amplified again in a second step by the variable gain amplifier 32a-2, the signal is shorted across the interstage switch 56 over a switch connection 60 between the switch terminals 58a and 58b. Due to the operation of the DPDT first stage RF switch 30a, a second pole connection 66a is established across the second set of throw terminals 42a and the second pole terminal 38a. In turn, the second pole terminal 38a of the first stage RF switch 30a is connected to the first pole terminal 36b of the second stage RF switch 30b as discussed above. In the second stage RF switch 30b, the first pole terminal 36b is connected to the second set of throw terminals 40b over a first pole connection 68a.

The output transmit signal from the first stage 52a is passed to the second stage 52b, and specifically to the input of the transmit-receive amplifier circuit 26-2. The signal is further amplified by the variable gain amplifier 32b, another phase shift is applied by the phase shifter 28″, then amplified by the power amplifier 34b. The output of the transmit-receive amplifier circuit 26-2 is passed to the second set of throw terminals, and over a second pole connection 70a, connected to the second pole terminal 38b. From there, the signal is passed to the antenna element 14a.

The schematic diagram of FIG. 5C illustrates the switch connections that are made during receive mode operation. The receive signal is provided by the antenna element 14a, and is passed to the second stage 52b, specifically the second pole terminal 38b of the second stage RF switch 30b. Over the switch connection 70b between the second pole terminal 38b and the first set of throw terminals 40b, the received signal is passed to the transmit-receive amplifier circuit 26-2, that is, the variable gain amplifier 32b, which is then shifted in phase by a prescribed amount, then amplified by the power amplifier 34b. The output of the power amplifier 34b/output of the transmit-receive amplifier circuit 26-2 is connected to the second set of throw terminals 42b of the second RF switch, and the amplified receive signal is passed to the first pole terminal 36b over the first pole connection 68b. In the receive mode operation, the interstage switch 56 is disconnected, so the input to the transmit-receive amplifier circuit 26 is not connected to the output of the variable gain amplifier circuit 62-1.

With the first pole terminal 36b of the second stage RF switch 30b being connected to the second pole terminal 38a of the first stage RF switch 30a, the partially amplified and phase-shifted receive signal is passed from the second stage 52b to the first stage 52a. Over a second pole connection 66b, the receive signal is passed to the first set of throw terminals 40a, then to the input of the variable gain amplifier circuit 62-1, and in particular, the first variable gain amplifier 32a-1. After this amplifier stage, the phase of the receive signal is shifted again through the phase shifter 28′ and amplified again by the second variable gain amplifier 32a-2. The amplified receive signal is passed to the second set of throw terminals 42a of the first stage RF switch 30a and passed to the first pole terminal 36a over the first pole connection 64b. From the first pole terminal 36a, the complete amplified and phase shifted receive signal is passed to the split port 22a of the splitter-combiner 18, where it is combined with the other receive signals from other receive chains, and output as a single receive signal from the RF input-output port 16.

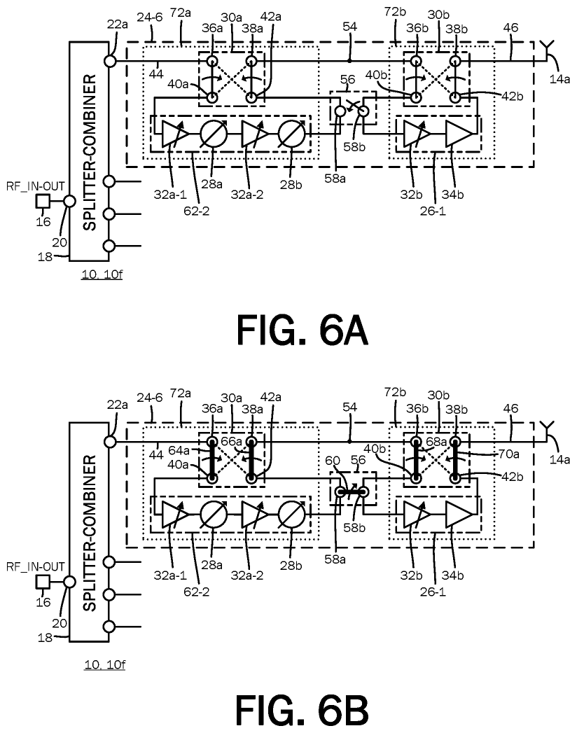

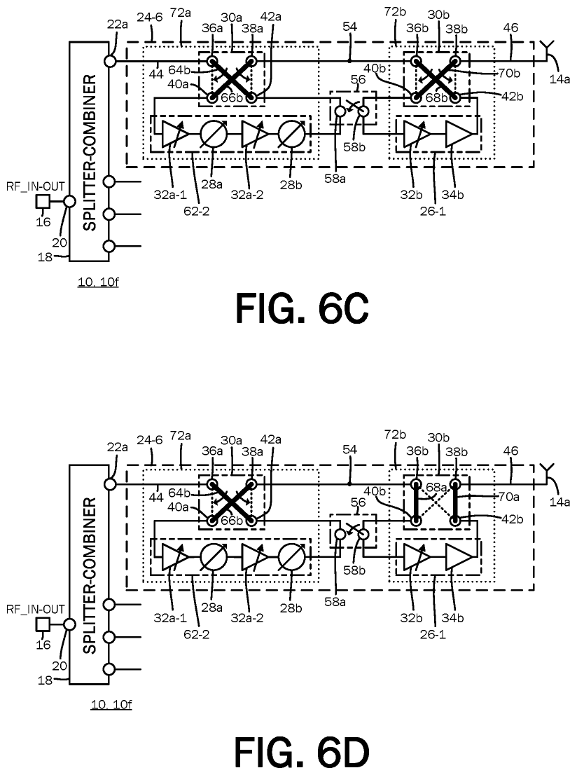

The schematic diagram of FIGS. 6A-6D illustrate still another variation on RF integrated circuit 10e incorporates a sixth variation of a transmit-receive circuit 24-6. As with all previously described embodiments, this embodiment has the RF input-output port 16 and the splitter-combiner 18 with the combined port 20 and the one or more split ports 22. The transmit-receive circuit 24-6 is connected to the first split port 22a and to the first antenna element 14a. While FIGS. 6A-6D do not show the other antenna elements 14 or the transmit-receive circuits 24, they are understood to be incorporated into the full embodiment; the depictions thereof in FIGS. 6A-6D have been removed for the sake of simplicity.

The transmit-receive circuit 24-6 is defined by the first stage 72a and a second stage 72b. The first stage 72a includes a first stage RF switch 30a with the first pole terminal 36a and the second pole terminal 38a. Additionally, the first stage RF switch 30a includes the first set of throw terminals 40a and the second set of throw terminals 42a. The first pole terminal 36a is in electrical communication with the split port 22 over the split-side junction 44, while the second pole terminal 38a is connected to the interstage junction 54.

The first stage 52a includes a second variation of a variable gain amplifier circuit 62-2, the input of which is connected to the first set of throw terminals 40a, and the output of which is connected to the second set of throw terminals 40b. The variable gain amplifier circuit 62-2 includes a first variable gain amplifier 32a-1, the input thereof corresponding to the overall input of the variable gain amplifier circuit 62-2. The output of the first variable gain amplifier 32a-1 is connected to the first port of the first phase shifter 28a, with the second port thereof being connected to the input of a second variable gain amplifier 32a-2. The output of the second variable gain amplifier 32a-2 is connected to the first port of the second phase shifter 28b. The second port of the second phase shifter 28b generally corresponds to the overall output of the variable gain amplifier circuit 62-2 and is connected to the second set of throw terminals 42a of the first stage RF switch 30a.

The second stage 72b likewise includes the second stage RF switch 30b with the first pole terminal 36b connected to the interstage junction 54. The second pole terminal 38b of the second stage RF switch 30b is connected to the antenna-side junction 46, which in turn is connected to the antenna element 14. The second stage 72b utilizes the first embodiment of the transmit-receive amplifier circuit 26-1 with the variable gain amplifier 32b and the power amplifier 34b, as discussed in detail above. In other words, as compared to the fifth embodiment of the transmit-receive circuit 24-5 described above, the second stage 72b eliminates the phase shifter 28″

The sixth variation of the transmit-receive circuit 24-6 further also utilizes the interstage switch 56 with one terminal 58a (e.g., the throw terminal) connected to the output of the variable gain amplifier circuit 62-2, and another switch terminal 58b (e.g., the pole terminal) connected to the input of the transmit-receive amplifier circuit 26-1. The interstage switch 56 may be a single pole, single throw switch that connects the output of the variable gain amplifier circuit 62-2 and the input of the transmit-receive amplifier circuit 26-1 together during the transmit mode. In the receive mode, the interstage switch 56 is disengaged to separate the respective output and input of the amplifier circuits 62-2 and 26-1. As will be described in further detail below, two different receive modes are also possible with the sixth variation of the transmit-receive circuit 24-6. One is the high sensitivity mode where the transmit-receive amplifier circuit 26-1 is turned on, and the other is a low current mode in which the transmit-receive amplifier circuit 26-1 is turned off to reduce the overall gain of the receive chain and concomitantly reduce DC current consumption. This mode may be used when a large signal level is received at the antenna element 14a, which may be either a usable signal or a blocking signal.

The schematic diagram of FIG. 6B illustrates the switch connections that are made during the transmit mode operation. The transmit signal is applied to the RF input-output port 16 and passed to the combined port 20 of the splitter-combiner 18 to be separated to multiple transmit chains. One of the split signals is output from the first split port 22a and passed to the first stage 72a of the transmit-receive circuit 24-6, and in particular, the first pole terminal 36a of first stage RF switch 30a. Over a first pole connection 64a, the first pole terminal 36a is connected to the first set of throw terminals 40a, and the transmit signal is passed to the input of the variable gain amplifier circuit 62-2. After being amplified in a first step by the variable gain amplifier 32a-1, passed through the first phase shifter 28a, amplified again in a second step by the variable gain amplifier 32a-2, the passed through the second phase shifter 28b, the signal is shorted across the interstage switch 56 over a switch connection 60 between the switch terminals 58a and 58b. Because of the operation of the DPDT first stage RF switch 30a, a second pole connection 66a is established across the second set of throw terminals 42a and the second pole terminal 38a. The second pole terminal 38a of the first stage RF switch 30a is connected to the first pole terminal 36b of the second stage RF switch 30b through the interstage junction 54 as discussed above. In the second stage RF switch 30b, the first pole terminal 36b is connected to the second set of throw terminals 40b over a first pole connection 68a.

The output transmit signal from the first stage 52a is passed to the second stage 52b, and specifically to the input of the transmit-receive amplifier circuit 26-1. The signal is further amplified by the variable gain amplifier 32b, then amplified by the power amplifier 34b. The output of the transmit-receive amplifier circuit 26-1 is passed to the second set of throw terminals, and over a second pole connection 70a, connected to the second pole terminal 38b. The signal is then passed to the antenna element 14a.

The schematic diagram of FIG. 6C illustrates the switch connections that are made during the high sensitivity receive mode operation. The receive signal is provided by the antenna element 14a, and is passed to the second stage 52b, specifically the second pole terminal 38b of the second stage RF switch 30b. Over the switch connection 70b between the second pole terminal 38b and the first set of throw terminals 40b, the received signal is passed to the transmit-receive amplifier circuit 26-1, which is the variable gain amplifier 32b and the power amplifier 34b. The output of the power amplifier 34b/output of the transmit-receive amplifier circuit 26-1 is connected to the second set of throw terminals 42b of the second RF switch, and the amplified receive signal is passed to the first pole terminal 36b over the first pole connection 68b. In the high sensitivity receive mode operation, the interstage switch 56 is disconnected, so the input to the transmit-receive amplifier circuit 26 is not connected to the output of the variable gain amplifier circuit 62-2.

With the first pole terminal 36b of the second stage RF switch 30b being connected to the second pole terminal 38a of the first stage RF switch 30a, the partially amplified and phase-shifted receive signal is passed from the second stage 52b to the first stage 52a. Over a second pole connection 66b, the receive signal is passed to the first set of throw terminals 40a, then to the input of the variable gain amplifier circuit 62-2, and in particular the first variable gain amplifier 32a-1. After this amplifier stage, the phase of the receive signal is shifted through the first phase shifter 28a and amplified again by the second variable gain amplifier 32a-2. This amplification stage is followed by another phase shift, as applied by the second phase shifter 28b. The amplified and phase-shifted receive signal is passed to the second set of throw terminals 42a of the first stage RF switch 30a and passed to the first pole terminal 36a over the first pole connection 64b. From the first pole terminal 36a, the complete amplified and phase shifted receive signal is passed to the split port 22a of the splitter-combiner 18, where it is combined with the other receive signals from other receive chains, and output as a single receive signal from the RF input-output port 16.

The schematic diagram of FIG. 6D illustrates the switch connections that are made during the low current receive mode operation. The receive signal is provided by the antenna element 14a, and is passed to the second stage 52b, specifically the second pole terminal 38b of the second stage RF switch 30b. The antenna element 14a is understood to be receiving a large signal level when the low current mode is active. The transmit-receive amplifier circuit 26-1 is turned off, and the second pole terminal 38b of the second stage RF switch 30b is connected to the second set of throw terminals 42b over the second pole connection 70a. Similarly, the first pole terminal 36a of the second stage RF switch 30b is connected to the first set of throw terminals 40b over the first pole connection 68a.

In the low current receive mode operation, the interstage switch 56 is disconnected.

The switch connections of the first stage 52a, however, are understood to be the same as those of the high sensitivity receive mode operation. Without being amplified, the received signal is passed to the second pole terminal 38a of the first stage RF switch 30a. Over the second pole connection 66b, the receive signal is passed to the first set of throw terminals 40a, then to the input of the variable gain amplifier circuit 62-2, and specifically the input of the first variable gain amplifier 32a-1 therein. After this amplifier stage, the phase of the receive signal is shifted through the first phase shifter 28a and amplified again by the second variable gain amplifier 32a-2. This amplification stage is followed by another phase shift as applied by the second phase shifter 28b. The amplified and phase-shifted receive signal is passed to the second set of throw terminals 42a of the first stage RF switch 30a and passed to the first pole terminal 36a over the first pole connection 64b. From the first pole terminal 36a, the complete amplified and phase shifted receive signal is passed to the split port 22a of the splitter-combiner 18, where it is combined with the other receive signals from other receive chains, and output as a single receive signal from the RF input-output port 16.

The particulars shown herein are by way of example and for purposes of illustrative discussion of the embodiments of the present disclosure only and are presented in the cause of providing what is believed to be the most useful and readily understood description of the principles and conceptual aspects. In this regard, no attempt is made to show details with more particularity than is necessary, the description taken with the drawings making apparent to those skilled in the art how the several forms of the present disclosure may be embodied in practice.

What is claimed is:

1. A phased array beamformer circuit connectible to an array of antenna elements, the circuit comprising:
a radio frequency (RF) input-output port;
one or more antenna ports each connectible to a respective one of the antenna elements;
a splitter-combiner including a combined port connected to the RF input-output port and one or more split ports;
one or more variable gain amplifier circuits each with an input and an output;
one or more power amplifier circuits each with an input and an output; and
one or more RF switches each with a first pole terminal connected to a split-side junction in electrical communication with a corresponding one of the split-ports of the splitter-combiner, a second pole terminal connected to an antenna-side junction in electrical communication with a corresponding one of the antenna ports, a first set of throw terminals and a second set of throw terminals each alternatingly connecting the first pole terminal to the input of a given one of the variable gain amplifier circuits and the output of a corresponding one of the power amplifier circuits connected thereto, and the second pole terminal to the output of the given one of the power amplifier circuits and the input of a corresponding one of the variable gain amplifier circuits connected thereto.

2. The phased array beamformer circuit of claim 1, further comprising:
one or more phase shifters each connected to a respective one of the split ports of the splitter-combiner and a respective one of the split side junctions to which the corresponding one of the first pole terminals of the RF switches is connected.

3. The phased array beamformer circuit of claim 2, wherein the phase shifters are bidirectional.

4. The phased array beamformer circuit of claim 1, further comprising:
one or more phase shifters each connected to the respective inputs of the variable gain amplifier circuits, the phase shifters being either unidirectional or bidirectional.

5. The phased array beamformer circuit of claim 1, further comprising:
one or more phase shifters each connected to an output of the variable gain amplifier circuits and an input of a corresponding one of the power amplifier circuits connected thereto.

6. The phased array beamformer circuit of claim 1, wherein each of the RF switches define a set of switch connections corresponding to a transmit mode and a receive mode.

7. The phased array beamformer circuit of claim 6, wherein in the transmit mode, the set of switch connections includes a first pole terminal of a given one the RF switches being connected to the input of the corresponding one of the variable gain amplifier circuits and a second pole terminal of the given one of the RF switches being connected to the output of the corresponding one of the power amplifier circuits.

8. The phased array beamformer circuit of claim 6, wherein in the receive mode, the set of switch connections includes a first pole terminal of a given one of the RF switches being connected to the output of the corresponding one of the power amplifier circuits and a second pole terminal of the given one of the RF switches being connected to the input of the corresponding one of the variable gain amplifier circuits.

9. The phased array beamformer circuit of claim 1, wherein isolation between the first pole terminal and the second pole terminal of a given one of the RF switches is at least 5 dB higher than a total combined gain of the variable gain amplifier circuit and the power amplifier circuit.

10. The phased array beamformer circuit of claim 1, wherein the variable gain amplifier circuits each includes a plurality of amplifier stages.

11. A phased array beamformer circuit connectible to an array of antenna elements, the circuit comprising:
a radio frequency (RF) input-output port;
one or more antenna ports each connectible to a respective one of the antenna elements;
a splitter-combiner including a combined port connected to the RF input-output port and one or more split ports;
one or more first amplifier circuits each with an input and an output;
one or more first RF switches each with a first pole terminal in electrical communication with a corresponding one of the split ports of the splitter-combiner, a second pole terminal, and a first set of throw terminals and a second set of throw terminals each alternatingly connecting the input and the output of a given one of the first amplifier circuits to the first pole terminal and the second pole terminal;
one or more second amplifier circuits each with an input and an output; and
one or more second RF switches each with a first pole terminal connected to the second pole terminal of a corresponding one of the first RF switches, a second pole terminal in electrical communication with a corresponding one of the antenna ports, and a first set of throw terminals and a second set of throw terminals each alternatingly connecting the input and the output of the second amplifier of a given one of the second amplifier circuits to the first pole terminal and the second pole terminal.

12. The phased array beamformer circuit of claim 11, wherein the first amplifier circuits each includes an input-side variable gain amplifier, an output-side variable gain amplifier, and a phase shifter interconnected between the input-side and output-side variable gain amplifiers.

13. The phased array beamformer circuit of claim 11, wherein the second amplifier circuits each includes a variable gain amplifier, a power amplifier, and a phase shifter interconnected between the variable gain amplifier and the power amplifier.

14. The phased array beamformer circuit of claim 11, further comprising:
one or more interconnect switches each selectively connecting the output of a given one of the first amplifier circuits to the input of a corresponding one of the second amplifier circuits.

15. The phased array beamformer circuit of claim 14, wherein:
in a transmit mode, the set of switch connections includes a first pole terminal and a second pole terminal of a given one of the first RF switches being connected to a respective input and an output of the corresponding one of the first amplifier circuits, a first pole terminal and a second pole terminal of a given one of the second RF switches being connected to a respective input and an output of the corresponding one of the second amplifier circuits, and terminals of the interconnect switch being connected; and
in a receive mode, the set of switch connections includes the first pole terminal and the second pole terminal of the given one of the first RF switches being connected to the respective output and the input of the corresponding one of the first amplifier circuits, the first pole terminal and the second pole terminal of the given one of the second RF switches being connected to the respective output and an input of the corresponding one of the second amplifier circuits, and the terminals of the interconnect switch being disconnected.

16. The phased array beamformer circuit of claim 11, wherein:
the first amplifier circuits each include an input-side variable gain amplifier, an output-side variable gain amplifier, an intermediate phase shifter interconnected between the input-side and output-side variable gain amplifiers, and an output-side phase shifter connected to the output-side variable gain amplifier.
the second amplifier circuits each include a variable gain amplifier and a power amplifier connected thereto.

17. The phased array beamformer circuit of claim 16, further comprising:
one or more interconnect switches each selectively connecting the output of a given one of the first amplifier circuits to the input of a corresponding one of the second amplifier circuits.

18. The phased array beamformer circuit of claim 17, wherein:
in a transmit mode, the set of switch connections includes a first pole terminal and a second pole terminal of a given one of the first RF switches being connected to a respective input and an output of the corresponding one of the first amplifier circuits, a first pole terminal and a second pole terminal of a given one of the second RF switches being connected to a respective input and an output of the corresponding one of the second amplifier circuits, and terminals of the interconnect switch being connected;
in a high sensitivity receive mode, the set of switch connections includes the first pole terminal and the second pole terminal of the given one of the first RF switches being connected to the respective output and the input of the corresponding one of the first amplifier circuits, the first pole terminal and the second pole terminal of the given one of the second RF switches being connected to the respective output and the input of the corresponding one of the second amplifier circuits, and the terminals of the interconnect switch being disconnected; and
in a low current receive mode, the set of switch connections includes the first pole terminal and the second pole terminal of the given one of the first RF switches being connected to the respective output and the input of the corresponding one of the first amplifier circuits, the first pole terminal and the second pole terminal of the given one of the second RF switches being connected to the respective input and the output of the corresponding one of the second amplifier circuits, and the terminals of the interconnect switch being disconnected.

19. A radio frequency integrated circuit connectible to an array of antenna elements, the integrated circuit comprising:
an RF input/output port;
antenna ports each connected to respective antenna elements of the array;
a transmit-receive amplifier circuit with an amplifier input and an amplifier output, the transmit-receive amplifier circuit being activated during both a transmit mode and a receive mode; and
an RF switch selectively connecting the amplifier input to the RF input/output port and the amplifier output to one of the antenna ports in a transmit mode, and the amplifier input to the one of the antenna ports and the amplifier output to the RF input/output port in a receive mode.

20. The radio frequency integrated circuit of claim 19, wherein switching between the transmit mode and the receive mode is completed under ten nanoseconds.
